(19) United States
(12) Patent Application Publication
(10) Pub. No.: US 2002/0093059 A1
(43) Pub. Date: Jul. 18, 2002

(54) Protective circuit for a semiconductor device

(75) Inventor: Shiro Tsunai, Tokyo (JP)

Correspondence Address: SUGHRUE MION, PLLC, 2100 Pennsylvania Avenue, N.W., Washington, DC, 20037-3213, US

(73) Assignee: NEC CORPORATION

(21) Appl. No.: 10/042,161

(22) Filed: Jan. 11, 2002

(30) Foreign Application Priority Data
Jan. 15, 2001 (JP) 2001-006774

(51) Int. Cl. H01L 23/62

(52) U.S. Cl. 257/362; 257/355; 257/360

(57) ABSTRACT

In a protective circuit, on a semiconductor substrate of a first conduction type an island-shaped first well of a second conduction type for formation of a protective element for bypassing the above-noted static electricity and a second well of the second conduction type biased to a prescribed potential and intended for formation of a circuit element of the internal circuit are formed so as to be mutually separated, the first well and the second well being connected via a resistance. By this configuration, when static electricity is applied the potential of the first well changes in response thereto, and a current flowing from the first well into the second well is appropriately suppressed, thereby preventing destruction of the internal circuit by the static electricity.

### BACKGROUND OF THE INVENTION

1. Field of the Invention

The present invention relates to a protective circuit for a semiconductor device for protecting an internal circuit on a semiconductor chip mounted in a package from destruction due to static electricity.

2. Related Art

The internal circuitry of a semiconductor device is generally made up of MOS (metal oxide semiconductor) field effect transistors (MOSFETs), with external signals being applied to the gates of MOSFETs serving as an input stages of the intended circuitry. There is a gate oxide film formed between a gate of a MOS field effect transistor and the semiconductor substrate, and this gate oxide film is destroyed by static electricity or the like applied via an external terminal. A protective circuit is therefore provided in a semiconductor device for the purpose of protecting the MOS field effect transistors in the internal circuitry from destruction by this type of static electricity.

FIG. 10 of the accompanying drawings shows an example of the configuration of a semiconductor device according to conventional technology. In this drawing, the reference numeral 110 denotes a signal terminal, 120 is a power supply terminal, and 130 is a ground (GND) terminal. In this example, the signal terminal 110 is an output terminal. The signal terminal 110, power supply terminal 120, and ground terminal 130 are formed as pad terminals on the semiconductor chip, and are electrically connected to external terminals (lead terminals) (not shown in the drawing) provided on the package in which this semiconductor chip is housed.

The reference numerals 940A, 940B, and 170 denote bipolar transistors serving as protective elements, these forming a protective circuit for the purpose of protecting the internal circuitry from static electricity applied to the signal terminal 110, as will be described further below. Of these, the current path of the bipolar transistor 940A is connected between the power supply terminal 120 and the signal terminal 110, the current path of the bipolar transistor 940B is connected between the ground terminal 130 and the signal terminal 110, and the current path of the bipolar transistor 170 is connected between the power supply terminal 120 and the ground terminal 130. The bases of these bipolar transistors 940A, 940B, and 170 are connected in common to the ground terminal 130.

The reference numeral 160 is an internal circuit of the semiconductor device, and is formed so as to include field effect transistors 160A and 160B. The current path of a field effect transistor 160A of the internal circuit 160 is connected between the ground terminal 120 and the signal terminal 110, while the current path of a field effect transistor 160B of the internal circuit 160 is connected between the ground terminal 130 and the signal terminal 110.

The gates of these field effect transistors are conduction controlled by a gate circuit (not shown in the drawing), so that either a high level or a low level is output from the internal circuit 160 toU the signal terminal 110.

FIG. 9 of the accompanying drawings shows the pattern layout in the area surrounding a bipolar transistor forming a protective circuit shown in FIG. 8 of the accompanying drawings. In this drawing, the reference numeral 910A denotes a pad electrode made of aluminum interconnect layer, this forming the above-noted signal terminal 110. The pad electrode 910A is electrically connected via bonding, with a wire of gold, or aluminum or the like, to an external terminal of the package (not shown in the drawing). The reference numeral 910B denotes a power supply interconnect layer connected to the above-noted power supply terminal 120, this being an aluminum interconnect layer. The reference numeral 910C is a ground interconnect connected the above-noted ground terminal 130, and connected to one end of the current path of the above-noted bipolar transistor 940B.

The reference numeral 910D is an aluminum interconnect layer connected to the pad electrode 910A, which is connected to the other end of the current path of the above-noted bipolar transistor 940B, and also connected to one end of the current path of the above-noted bipolar transistor 940A. The reference numeral 910E denotes an aluminum interconnect layer, which is electrically connected to the other end of the bipolar transistor 940A and connected via an n-type diffusion region 920 to the power supply interconnect 910B. The reference numeral 930 is a contact hole for the purpose of electrical connection between aluminum interconnects layer and an impurity diffusion region on the substrate. The reference numeral 950 is a p-type well, the above-noted bipolar transistors 940A and 940B being formed therewithin.

FIG. 10 of the accompanying drawings shows a cross-sectional view of FIG. 9, cut along the line X-X. In this drawing, the reference numeral 900 denotes an n-type semiconductor substrate. A p-type well and the diffusion regions for various transistors are formed on this semiconductor substrate. The reference numeral 960 denotes an oxide film formed on the substrate, this serving as an insulation film. The reference numeral 970 denotes a channel stopper layer formed at the boundary between the oxide film 960 and the semiconductor substrate. Although it is not shown in this drawing, an interlayer insulation film is formed on the oxide film 960, an onto this interlayer insulation film is formed an aluminum interconnect layer such as the power supply interconnect 910B. The aluminum interconnect layer and impurity diffusion region on the semiconductor substrate are electrically connected via a contact hole formed in the interlayer insulation film.

FIG. 11 is a cross-sectional view focused on the current paths for static electricity. In this drawing, the reference numeral 960 a p-type impurity diffusion region, and 940 is a field effect transistor forming part of the internal circuit 960. The p-type well 950 is connected to the ground terminal 130 via the p-type impurity diffusion region 960. This p-type impurity diffusion region 960 biases the p-type well 950 to the ground potential, and improves the electrical (ohmic) connection condition between the ground terminal 130 and the p-type well 950. As shown in the drawing, the bipolar transistors 940A and 940B and the field effect transistor 940C of the internal circuit 160 are formed in one and the same p-type well 950.

The operation of the protective circuit according to the conventional technology is described below.

If a voltage is applied because of static electricity between the signal terminal 110, which is an output terminal, and the power supply terminal 120, the bipolar transistor 940A and the field effect transistor 160A of the internal circuit form a bypass path for current caused by the static electricity. Because of this, the static electricity is discharged in a condition in which the current densities flowing the transistors is held to a small size, thereby protecting the internal circuit from destruction. In the same manner, if a voltage is applied because of static electricity between the ground terminal 130 and the signal terminal 110, the bipolar transistors 940B and the field effect transistor 160B protect the internal circuit by forming a bypass path.

One possible form of countermeasure for static electricity at an output terminal is that causing the field effect transistor serving as an output buffer to act as a protective element. In this case, the size (for example, the gate width) of the output buffer field effect transistor is made large, so as to increase the current capacity of that transistor. By doing this, there is an improvement in the discharging capacity of the bypass path for current caused by static electricity, thereby protecting the internal circuit 160 from destruction.

With regard to an input terminal, because an input terminal is generally connected to the gate of an input stage of the internal circuit, there is no current bypass path such as noted above formed by the field effect transistors 160A and 160B. For this reason, if a countermeasure is to be provided with respect to static electricity, a protective element similar to the above-described bipolar transistors 940A and 940B is provided between each input terminal and the power supply terminal and the ground terminal, and the size of these protective elements is made sufficiently large. By doing this, surge currents caused by static electricity tend to flow into the protective elements, thereby effectively discharging the static electricity applied to the input terminals. By doing this, there is almost no surge voltage caused by static electricity applied to the internal circuit, thereby protecting the internal circuit from the static electricity.

In recent years, with the shrinking size of device structures, there has been a reduction in the withstand voltage of various parts of MOS field effect transistors, leading to a tendency of destruction by static electricity. This reduction in size has brought with it a decrease in the withstand voltage of even the protective circuits themselves, which are provided to protect the internal circuit from destruction by static electricity. Therefore, in order to protect the internal circuit from destruction by static electricity, it is necessary to avoid destruction of the protective circuit itself and, as there is a further reduction in the size of elements there is the problem of requiring a protective element that occupies a large surface area.

Accordingly, given the above-described situation with regard to static electricity protection, it is an object of the present invention to provide a protective circuit for a semiconductor device, which is capable of improving the static electricity immunity of a semiconductor device without an accompanying increase in surface area occupied by the formation of a static electricity discharge path.

### SUMMARY OF THE INVENTION

In order to achieve the above-noted objects, the present invention adopts the following basic technical constitution.

Specifically, a protective circuit for a semiconductor device according to the present invention is a protective circuit for protecting the internal circuit of a semiconductor device from static electricity, this protective circuit having on a semiconductor substrate of a first conduction type (for example a constituent element corresponding to an n-type semiconductor substrate 200 to be described below) an island-shaped first well of a second conduction type (for example, a constituent element corresponding to a p-type well 150 to be described below) intended for formation of a protective element for bypassing the above-noted static electricity and a second well of the second conduction type (for example, a constituent element corresponding to the p-type well 190 described below) biased to a prescribed potential and intended for formation of a circuit element of the internal circuit, these being formed so as to be mutually separated, the first well and the second well being connected via a resistance (for example, a constituent element corresponding to the resistance 180 to be described below).

In this protective circuit for a semiconductor device, the protective element operates, for example, as a punch-through transistor.

Additionally, in the above-noted protective circuit for a semiconductor device, the protective element is, for example, a MOS field effect transistor.

In the protective circuit for a semiconductor device noted above, the protective element is, for example, a bipolar transistor.

According to the present invention, because the first well for the formation of a protective element and the second well for the formation of a circuit element of the internal circuit are formed so as to be separate, the first and second wells being connected via a resistance, the current flowing in the protective element is appropriately suppressed. Therefore, the internal circuit is protected from static electricity without the protective element being destroyed by the static electricity. Because it is not necessary to provide a resistance between the signal terminal and the internal circuit in order to provide protection of the semiconductor device from destruction, it is possible to obtain a protective circuit suitable for circuits operating at a high speed. Additionally, for a given amount of immunity to static electricity, compared with conventional technology the size of the protective element between each terminal and the power supply can be made smaller, thereby making possible a reduction in the chip size. Stated in reverse, for a given protective element occupied surface area, it is possible to achieve a greater immunity to static electricity (for example a two-fold increase) than with a conventional protective circuit.

### BRIEF DESCRIPTION OF THE DRAWINGS

FIG. 1 is a circuit diagram showing the general configuration of a semiconductor device according to a first embodiment of the present invention.

FIG. 2 is a drawing showing an example of a layout pattern of a protective circuit according to the first embodiment of the present invention.

FIG. 3 is a drawing showing an example of the cross-sectional structure of a semiconductor chip on which is formed a protective circuit according to the first embodiment of the present invention.

FIG. 4 is a drawing illustrating the operation of a protective circuit according to the first embodiment of the present invention.

FIG. 5 is a circuit diagram showing the general configuration of a semiconductor device according to a second embodiment of the present invention.

FIG. 6 is a drawing showing an example of the layout pattern of a protective circuit according to the second embodiment of the present invention.

FIG. 7 is a drawing showing an example of the cross-sectional structure of a semiconductor chip on which is formed a protective circuit according to the second embodiment of the present invention.

FIG. 8 is a circuit diagram showing the general configuration of a semiconductor device according to conventional technology.

FIG. 9 is a drawing showing an example of the layout pattern of a protective circuit according to conventional technology.

FIG. 10 is a drawing showing an example of the cross-sectional structure of a semiconductor device on which is formed a protective circuit according to conventional technology.

FIG. 11 is a drawing illustrating the operation of a protective circuit according to conventional technology.

### DETAILED DESCRIPTION OF THE PREFERRED EMBODIMENTS

Embodiments of the present invention are described in detail below, with reference made to relevant accompanying drawings.

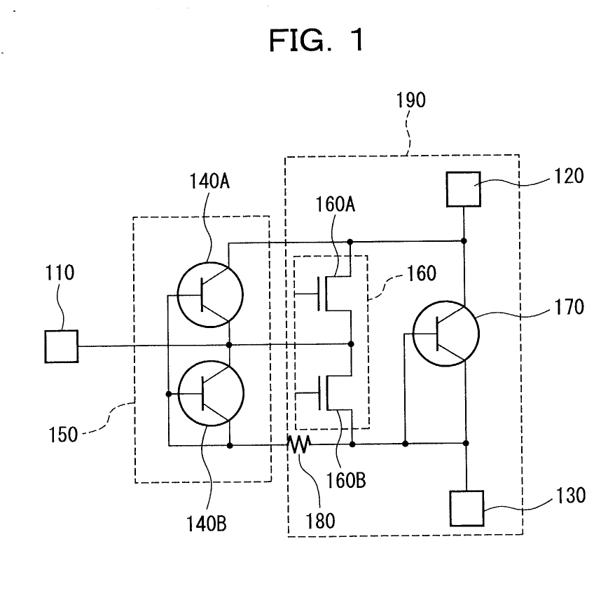

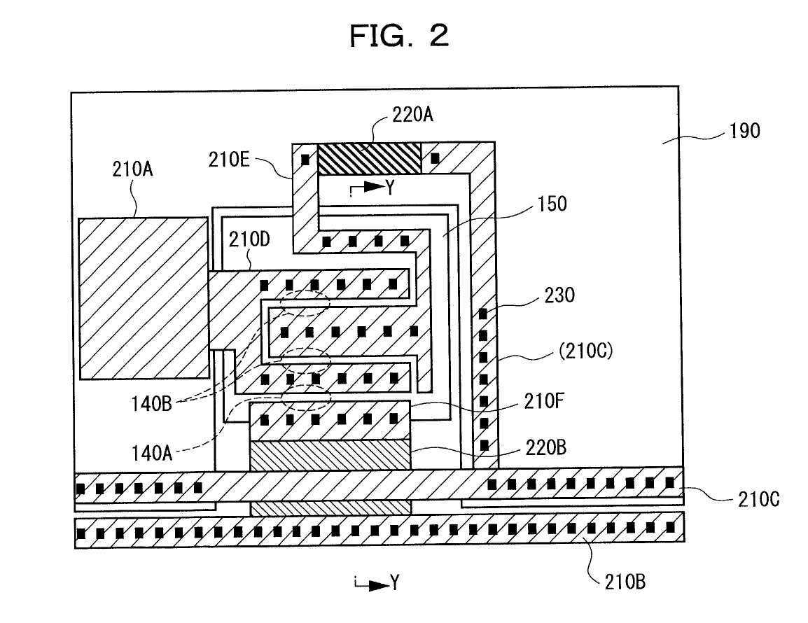

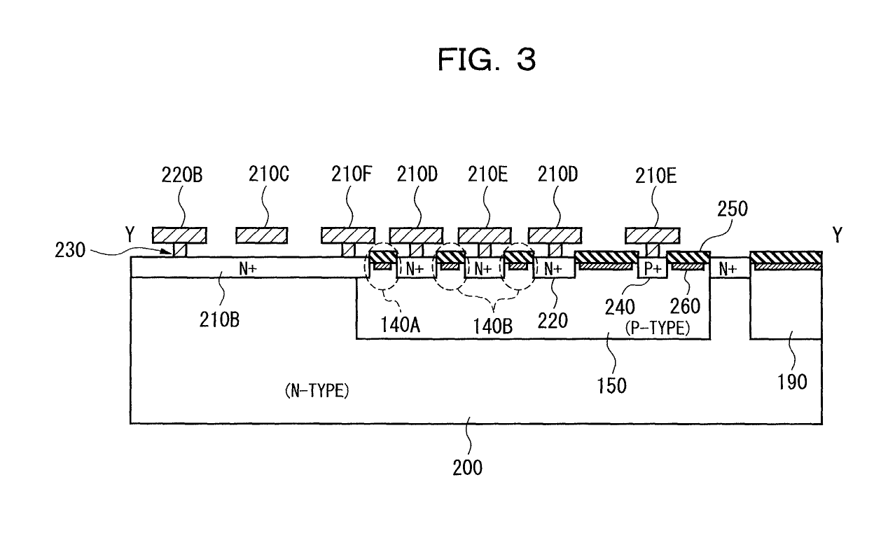

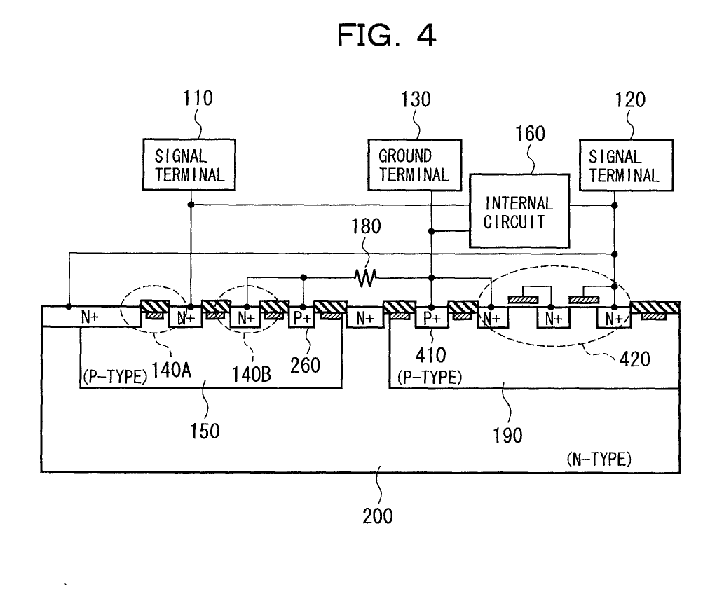

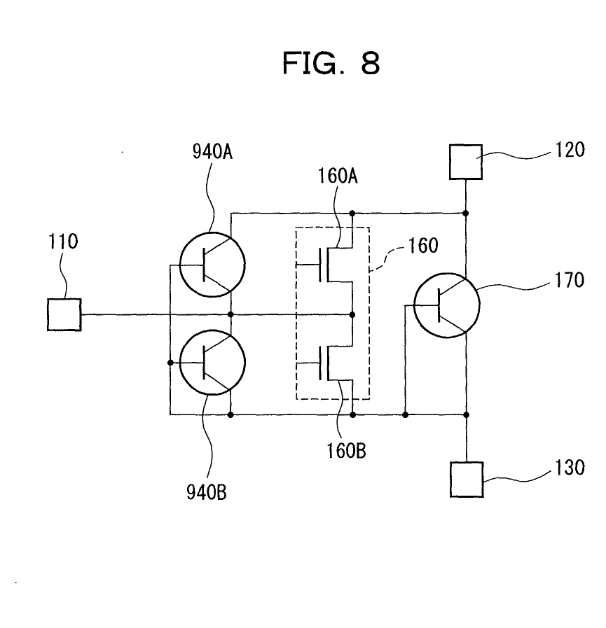

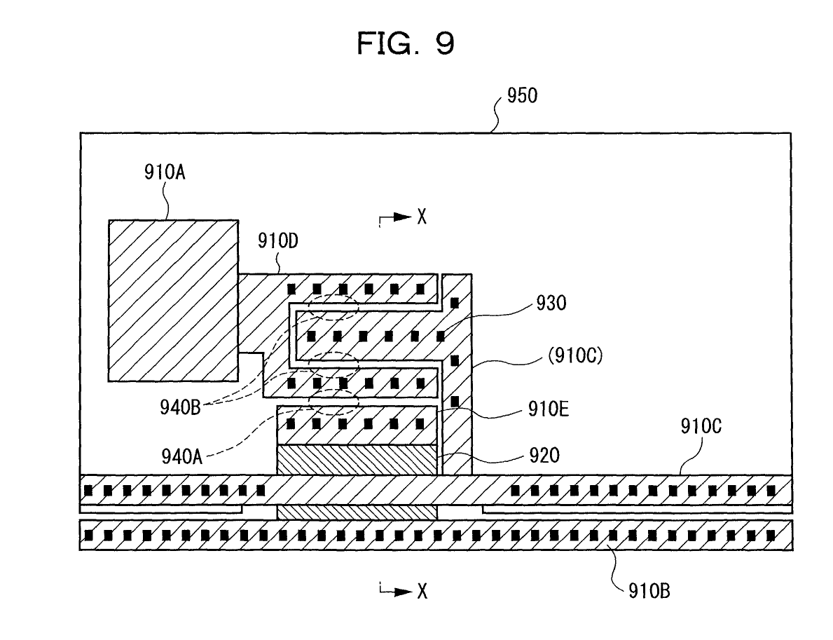

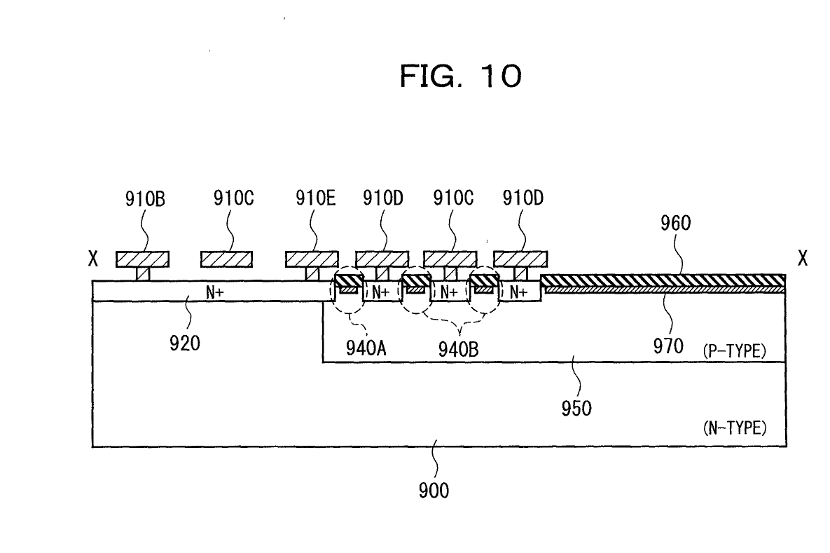

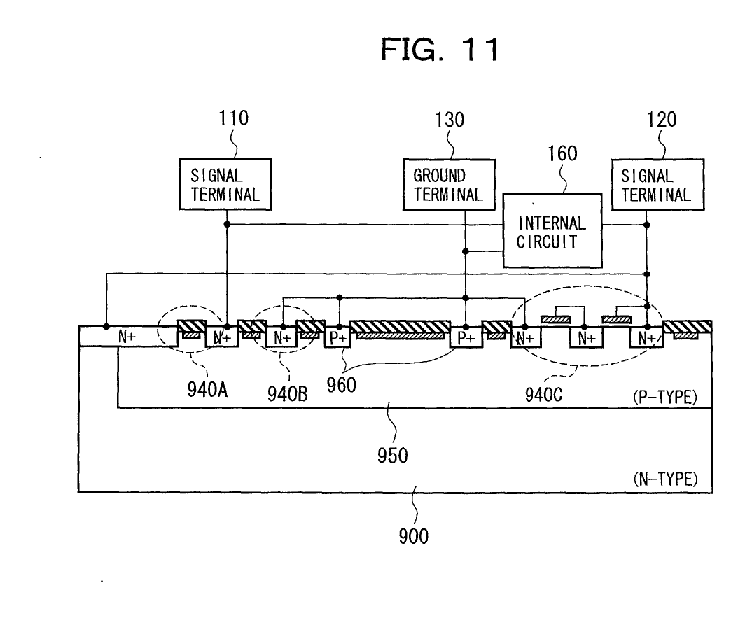

Specifically, FIG. 1 shows the general configuration of a semiconductor device to which a protective circuits according to a first embodiment of the present invention is applied. FIG. 2 is a drawing of the layout pattern of this protective circuit. FIG. 3 is a structural cross-sectional view of a semiconductor chip on which is formed this protective circuit. FIG. 4 is a schematic cross-sectional view illustrating the flow of electrical charges when a static electricity is applied. In each of these drawings, the reference numerals applied are the same as applied to elements of FIG. 8 through FIG. 11.

In a protective circuit of a semiconductor device according to this embodiment having a configuration shown in FIG. 8, bipolar transistors 140A and 140B are formed as protective elements in a p-type well 150, and a p-type well 190, in which an internal circuit 160 is formed, is additionally formed, separated from the p-type well 150, the p-type well 150 and the p-type well 190 being connected by a resistance 180, which is formed by an n-type impurity diffusion region. The configuration is described in further detail below.

In FIG. 1, reference numeral 110 denotes a signal terminal, 120 is a power supply terminal, and 130 is a ground terminal (GND).

The signal terminal 110, the power supply terminal 120, and the ground terminal 130 are formed as pad electrodes on a semiconductor chip, and are electrically connected to external terminals (lead electrodes) provided on a package within which the semiconductor chip is housed. In this example, the signal terminal 110 is an output terminal.

The reference numerals 140A, 140B, and 170 denote bipolar transistors serving as protective elements for bypassing static electricity applied to the signal terminal 110, these functioning as punch-through transistors. These bipolar transistors 140A, 140B and 170 form a protective circuit (with no reference numeral applied) for protecting the internal circuit, to be described below, from static electricity.

In this case, the bipolar transistors 140A and 140B are formed within an island-shaped p-type well 150, and the internal circuit 160 is formed within a p-type well 190. The p-type wells 150 and 190 are formed separate from one another, and are mutually connected via a resistance 180. Of these, the p-type well 190 is connected to a pad electrode 130, and biased via the pad electrode 130 to the ground potential (prescribed potential). The other p-type well 150 is indirectly biased to the ground potential via the resistance 180 and the p-type well 190.

Of the bipolar transistors 140A, 140B, and 170, the current path of the bipolar transistor 140A is connected between the power supply terminal 120 and the signal terminal 110, the current path of the bipolar transistor 140B is connected between the ground terminal 130 (GND) and the signal terminal 110, and the current path of the bipolar transistor 170 is connected between the power supply terminal 120 and the ground terminal 130 (GND). The bases of the bipolar transistors 140A and 140B are formed from the above-noted p-type well 150, and the base of the bipolar transistor 170 is formed from the above-noted p-type well 190. Because the p-type wells 150 and 190 are connected in common to the ground terminal 130, the bases of the bipolar transistors 140A, 140B, and 170 are biased to the ground potential.

The reference numeral 160 denotes an internal circuit of this semiconductor device, this encompassing the field effect transistors 160A and 160B. Of these, the current path of field effect transistor 160A is connected between the power supply terminal 120 and the signal terminal 110, and the current path of the field effect transistor 160B is connected between the ground terminal 130 and the signal terminal 110. The gates of these field effect transistors are conduction controlled by a circuit system not illustrated in the drawing, so that the a high level or a low level is output from the internal circuit 160 to the signal terminal 110.

FIG. 2 shows the layout pattern of the bipolar transistors 140A and 140B and the surrounding area. In this drawing, the reference numeral 210A denotes a pad electrode made of aluminum interconnect layer, this forming the above-noted signal terminal 110. The pad electrode 210A is electrically connected to an external terminal of a package (not shown in the drawing) via a bonding wire made of gold, aluminum or the like. The reference numeral 210B is a power supply interconnects layer connected to the above-noted power supply terminal 120, this being made of aluminum interconnects layer. The reference numeral 210C denotes a ground interconnects layer connected to the above-noted ground terminal 130, this being made of aluminum interconnects layer.

The reference numeral 210D denotes an aluminum interconnect layer connected to the pad electrode 210A, this being connected to the other terminal side of the current pass of the above-noted bipolar transistor 140B, and connected to one end of the current pass of the above-noted bipolar transistor 140A. The reference numeral 210E denotes an aluminum interconnect layer connected to one end of the above-noted bipolar transistor 140B. The reference numeral 220A is an n-type impurity diffusion region which forms the above-noted resistance 180, one end of which is connected to the aluminum interconnect layer 210E, and the other end of which is connected to the ground interconnect 210C.

The reference numeral 210F is an aluminum interconnect layer connected to one end of the current path of the above-noted bipolar transistor 140A, and connected via the n-type impurity diffusion region 220B to the power supply interconnect 210B. The reference numeral 230 denotes a contact hole for making electrical connection between the aluminum interconnect layer and the impurity diffusion region on the substrate. The above-noted bipolar transistors 140A and 140B are formed within the p-type well 150, and the internal circuit 160 and bipolar transistor 170 are formed within the p-type well 190.

FIG. 3 shows the cross-sectional construction of the structure of FIG. 2, cut along the line Y-Y. In this drawing, the reference numeral 200 denotes an n-type semiconductor substrate. On this semiconductor substrate are formed p-type wells 150 and 190, and an n-type impurity diffusion region 220A as the resistance 180. The reference numeral 250 denotes an oxide film, which serves as an insulation film. The reference numeral 260 denotes a channel stopper layer.

Although it is not shown in this drawing, an interlayer insulation film is formed on the oxide film 250, and on this interlayer insulation film is formed various aluminum interconnect layers, such as the power supply interconnect 210B or the like.

These aluminum interconnect layers and impurity diffusion region on the semiconductor substrate 200 are electrically connected by means of contact holes 230, which are formed in the interlayer insulation film.

FIG. 4 is a drawing showing the cross-sectional structure, focusing on static electricity current paths. In this drawing, the reference numerals 260 and 410 are p-type impurity diffusion regions, and the reference numeral 420 is a field effect transistor forming part of the internal circuit 160. The p-type well 150 is connected to the ground terminal 130 via the p-type impurity diffusion region 260 and the resistance 180 (n-type impurity diffusion region 220A), and the p-type well 190 is connected to the ground terminal 130 via the p-type impurity diffusion region 410. The p-type impurity diffusion regions 260 and 410 are formed so as to improve the electrical (ohmic) connection condition between the ground terminal 130 and the p-type wells 150 and 190 when the p-type wells 150 and 190 are biased to the ground potential.

As shown in the drawing, the bipolar transistors 140A and 140B and the internal circuit 160 are formed within separate p-type wells 150 and 190.

As described above, a protective circuit is formed in the area near the signal terminal. The signal terminal and the protective circuit are connected by an interconnect material such as aluminum or copper. The p-type well 150 of the protective circuit part is formed in an island-shaped region electrically separated from the p-type well 190 having the internal circuit and the like. Within this island-shaped region, protective elements are formed between the signal terminal and the ground terminal, and between the signal terminal and the power supply terminal, respectively. The p-type well of the protective circuit part is connected to the p-type well (ground potential) of the internal circuit part, via interconnects and resistors.

In FIG. 2, although there is a n-type impurity diffusion region making connection between the aluminum interconnect layer 210F and the power supply interconnect 210B, this can be merely an interconnect layer.

Taking the example of testing for static electricity breakdown, the operation of the protective circuit according to this embodiment of the present invention is described below.

In tests of static electricity breakdown, there is a test whereby a positive or a negative voltage is applied to the signal terminal 110 with respect to the ground terminal 130, and a test whereby a positive or a negative voltage is applied to the signal terminal 110 which is positive or negative with respect the power supply terminal 120. First, a static electricity voltage is applied to the signal terminal 110 that is positive with respect to the ground terminal 130, so that the punch-through transistor forming the bipolar transistor 140B connected between the signal terminal 110 and the ground terminal 130 is turned on, the static electricity charge applied to the signal terminal 110 being caused to discharge to the ground interconnect 210C connected to the ground terminal 130, via this punch-through transistor, thereby preventing the destruction of the internal circuit 160.

The on voltage of the bipolar transistor 140B is generally higher than the absolute maximum rated voltage (maximum voltage when the semiconductor device is operated), and is set so that it is lower than the breakdown voltage of the internal circuit 160. The on voltage of the bipolar transistor 140B is controlled by the withstand voltage of a PN junction. This withstand voltage is, for example, controlled by the ion implantation concentration of the p-type impurity diffusion region and the n-type impurity diffusion region. The relationship between the withstand voltage of a PN junction and the ion implantation concentration is indicated in existing publications. The current that escapes from the internal circuit 160 to the ground terminal interconnect 210C escapes to the ground terminal 130 via the resistance 180 (n-type impurity diffusion region).

In the case in which negative static electricity with respect to the ground terminal 130 is applied to the signal terminal 110, the n-type impurity diffusion region connected to the signal terminal 110 is biased negatively and the p-type well 190 in which the internal circuit 160 is formed is biased positively. As a result, a forward current passes through the PN junctions between the n-type impurity diffusion regions of the bipolar transistors 140A and 140B (emitters and collectors) and the p-type well 150 (bases), so that the static electricity is discharged, thereby preventing destruction of the internal circuit 160.

In this case, because the p-type well 150 of the protective circuit part is formed separately for the p-type well 190 in which the internal circuit 160 is formed, the static electricity charge first enters the p-type well 150 of the protective circuit part, and then escapes to the aluminum interconnect layer 210 shown in FIG. 2. In the case in which the resistance 180 is formed as an n-type impurity diffusion region within the p-type well 190, electrons flow again from this n-type impurity diffusion region into the p-type well 190, and current flows to the ground interconnect 210C (ground terminal 130) via the p-type impurity diffusion region existing nearby. In this case, because there is substantially no current flowing in the resistance 180, the resistance 180 does not limit the current capacity of the bipolar transistor in acting as a protective element.

Additionally, in the case in which static electricity positive with respect to the power supply terminal 120 is applied to the signal terminal 110, in the same manner as in the case in which static electricity positive with respect to the ground terminal 130 is applied to the signal terminal 110, the static electricity is discharged via the bipolar transistor 140A, thereby preventing the destruction of the internal circuit 160. The on voltage of the punch-through transistor forming the power supply side bipolar transistor 140 can be set to the same voltage as the bipolar transistor 140B on the ground side.

Additionally, in the case in which static electricity that is negative with respect to power supply terminal 120 is applied to the signal terminal 110, electrons are injected from the n-type impurity diffusion region of the bipolar transistors 140A and 140B connected to the signal terminal 110 into the p-type well 150. Because this p-type well 150 is independent from other p-type wells, the electrons injected into the p-type well 150 modulated the potential of the p-type well 150 in the negative direction. When this occurs, the electrons injected into the p-type well 150 are split into two paths, one being a path of escape to the n-type impurity diffusion region 200 and the power supply terminal 120 via eh power supply side bipolar transistor 140A, and the other being the path of escape to the power supply terminal 120 via the ground-side bipolar transistor 140B, the p-type impurity diffusion region 260 of the p-type well 150, the protective resistance 180, the ground interconnect 210C, and the internal circuit 160.

In this case, although there is no particular problem cause by a current flowing via the power supply side bipolar transistor 140A, there is a danger that the current flowing via the ground interconnect and the internal circuit 160 will destroy the internal circuit 160. However, because of the protective resistance 180 the current flowing into the internal circuit 160 is appropriately suppressed, thereby preventing destruction of the internal circuit.

The larger is the resistance value of the protective resistance 180, the more difficult it is for destruction of the internal circuit to occur. However, because the potential of the p-type well 150 in which is form the bipolar transistor becomes unstable, there is a danger of latch-up occurring. Therefore, the resistance value of the protective resistance 180 must be established with latch-up immunity in mind. As one example, in order to achieve both prevention of latch-up and sufficient protective capability, the resistance value of the resistance 180 is set in the approximate range from 50 Ù to 300 Ù.

A second embodiment of the present invention is described below.

Whereas in the above-described first embodiment bipolar transistors 140A and 140B are used as protective elements, in the second embodiment n-type MOS field effect transistors 510A and 510B are used as protective elements. These n-type MOS field effect transistors 510A and 510B function as punch-through transistors, in the same manner as the bipolar transistors 140A and 140B.

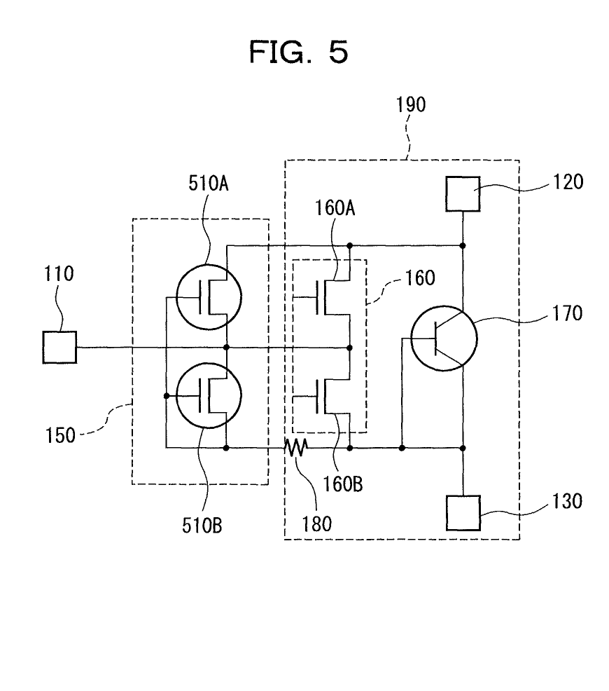

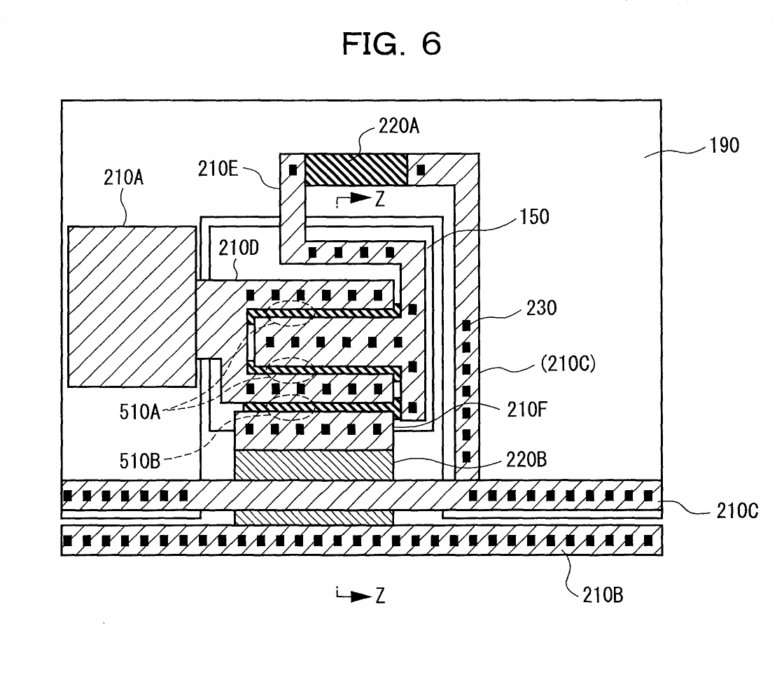

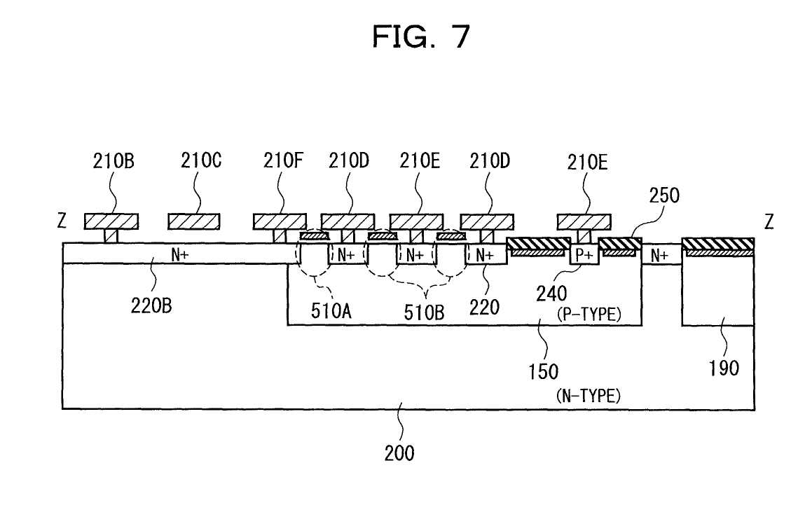

FIG. 5 is a drawing showing the general configuration of a semiconductor device to which the protective circuit according to the second embodiment of the present invention is applied. FIG. 6 shows the layout pattern in the area surrounding the protective element that forms the protective circuit. FIG. 7 is a structural cross-sectional view of a semiconductor chip on which is formed this protective circuit, shown cut along the line Z-Z of FIG. 6. FIG. 8 is a schematic cross-sectional view illustrating the discharge path for electrical charge (static electricity) when static electricity is applied. FIG. 5 through FIG. 8 corresponds to FIG. 1 through FIG. 4 with regard to the first embodiment.

In FIG. 5 through FIG. 8, elements in common with elements in FIG. 1 through FIG. 4 are assigned the same reference numerals.

The operation and effect of the second embodiment are similar to those of the first embodiment. That is, in the case in which static electricity positive with respect to the ground terminal 130 is applied to the signal terminal 110, the n-type MOS field effect transistor 510B connected between the signal terminal 110 and the ground terminal 130 is switched on, so as to cause the static electricity to discharge to the ground terminal side. In the case in which static electricity negative with respect to the ground terminal 130 is applied to the signal terminal 110, forward current flows between the n-type impurity diffusion region (source-drain) of the n-type MOS field effect transistors 510A and 510B and p-type well 150, so that the static electricity is discharged to the ground terminal 130.

Additionally, in the case in which static electricity negative with respect to the power supply terminal 120 is applied to the signal terminal 110, similar to the case in which static electricity positive with respect to the ground terminal 130 is applied to the signal terminal 110, static electricity is discharged via the n-type MOS field effect transistor 510A. Additionally, in the case in which static electricity negative with respect to the power supply terminal 120 is applied to the signal terminal 110, electrons are injected into the p-type well 150 from the n-type impurity diffusion regions of the bipolar transistors 140A and 140B connected to the signal terminal 110.

Electrons injected in the p-type well 150 split into two paths, one being a path of escape to the power supply terminal 120 via the power supply side bipolar transistor 140A, and the other being the path of escape to the power supply terminal 120 via the ground-side bipolar transistor 140B. Of these, the current that escapes to the power supply terminal 120 via the ground-side bipolar transistor 140B flows in the internal circuit 160, but this current is appropriately suppressed by the protective resistance 180.

From the above, the internal circuit 160 is protected from static electricity.

The first and second embodiments of the present invention achieve the following effects.

(1) According to a protective circuit of the present invention, because the p-type well 150 of the protective circuit 160 is formed in the shape of an island independently from the p-type well of another element part, and each p-type well is connected with a protective resistance 180, it is easy for the potential of the p-type well 150 in which the protective circuit is formed to change. For this reason, the on voltage of the punch-through transistors that form the protective circuit (bipolar transistors 140A and 140B and n-type MOS field effect transistors 510A and 510B) is low in comparison with the condition of steady state use with respect to pulse electrical charges from, for example, static electricity, thereby achieving the effect of increasing the immunity of the semiconductor device with respect to static electricity.

(2) According to a protective circuit of conventional technology, in the case of the static electricity breakdown test mode in a voltage that is negative with respect to power supply terminal is applied to various terminals, a current applied as static electricity flows directly into the protective circuit. In contrast to this, according to a protective circuit of the present invention because the protective resistance 180 suppresses current flowing into the protective circuit, it is difficult for destruction of the internal circuit to occur. More specifically, it has been verified that in an HBM (human body model) static electricity test, the static electricity withstand voltage is improved by a factor of two.

Although the present invention is described above for the case of embodiments, it will be understood that the present invention is not restricted to the above-described embodiments, and can take other various forms, within the technical scope of the present invention.

For example, the protective resistance 180 in the present invention can be a resistance of an impurity diffusion region (n-type impurity diffusion region, p-type impurity diffusion region), a polysilicon resistance, or a resistor which uses an MOS field effect transistor or the like. The protective element can be a transistor, an enhancement-type n-type MOS field effect transistor, a p-type MOS field effect transistor, and can further be a combination thereof.

It is further possible to replace the p-type constituent elements (for example, the p-type MOS field effect transistors) with n-type MOS field effect transistors and replace the n-type constituent elements (for example, the n-type MOS field effect transistors) with p-type MOS field effect transistors. In the case of forming an n-type well in a p-type well (or on a p-type substrate), it is possible to achieve the same type of effect by forming protective element separately in n-type well within a p-type well (or on a p-type substrate).

According to the present invention, in a protective circuit for protecting a circuit element within a semiconductor device from static electricity, on a semiconductor substrate of a first conduction type an island-shaped first well of a second conduction type for formation of a protective element for bypassing the above-noted static electricity and a second well of the second conduction type biased to a prescribed potential and intended for formation of a circuit element of the internal circuit are formed so as to be mutually separated, the first well and the second well being connected via a resistance. By virtue of this configuration, it is possible to improve the immunity to static electricity, without an accompanying increase in the surface area occupied by the protective transistors forming the discharge path for static electricity.

What is claimed is:

1. A protective circuit for a semiconductor device, comprising:
an island-shaped first well of a second conduction type intended for formation of a protective element for bypassing static electricity and a second well of the second conduction type biased to a prescribed potential and intended for formation of a circuit element of an internal circuit, are formed on a semiconductor substrate of said first conduction type so as to be mutually separated, said first well and said second well being connected via a resistance.

2. A protective circuit according to claim 1, wherein at least a part of said protective element functions as a punch-through transistor.

3. A protective circuit according to claim 2, wherein at least a part of said protective circuit is an MOS field effect transistor.

4. A protective circuit according to claim 2, wherein said protective circuit is a bipolar transistor.
